(19) United States
(12) Patent Application Publication
(10) Pub. No.: US 2019/0138455 A1
(43) Pub. Date: May 9, 2019

(54) MEMORY CONTROLLER AND METHOD OF OPERATING THE SAME

(71) Applicant: SK hynix Inc., Gyeonggi-do (KR)

(72) Inventor: Dong Jae SHIN, Gyeonggi-do (KR)

(21) Appl. No.: 16/028,570

(22) Filed: Jul. 6, 2018

(30) Foreign Application Priority Data
Nov. 8, 2017 (KR) 10-2017-0148125

(51) Int. Cl. G06F 12/1009; G06F 3/06

(52) U.S. Cl. CPC G06F 12/1009; G06F 3/0604; G11C 16/0483; G06F 3/0679; G06F 3/0659

(57) ABSTRACT

Provided herein may be a memory controller and a method of operating the same. The memory controller controls a semiconductor memory device including a plurality of pages. The memory controller may include a processing unit and a command control unit. The processing unit receives a command and a logical address corresponding to the command from a host, and generates a command physical address by converting the logical address. The command control unit temporarily stores a cache physical address corresponding to cache data that is cached in a page buffer of the semiconductor memory device and converts the command by comparing the cache physical address to the command physical address.

### CROSS-REFERENCE TO RELATED APPLICATION

The present application claims priority under 35 U.S.C. § 119(a) to Korean patent application number 10-2017-0148125, filed on Nov. 8, 2017, which is incorporated herein by reference in its entirety.

### BACKGROUND

### 1. Field of Invention

Various embodiments of the present disclosure generally relate to an electronic device. Particularly, the embodiments relate to a memory controller and a method of operating the memory controller.

### 2. Description of the Related Art

A memory device may have a two-dimensional (2D) structure in which strings are horizontally arranged on a semiconductor substrate. Alternatively, the memory device may have a three-dimensional (3D) structure in which strings are vertically stacked on a semiconductor substrate. As the 2D structure is reaching its integration limitations, semiconductor manufacturers are producing 3D memory devices that include a plurality of memory cells vertically stacked on a semiconductor substrate.

### SUMMARY

Various embodiments of the present disclosure are directed to a memory controller, which has improved reliability.

Various embodiments of the present disclosure are directed to a method of operating a memory controller, which has improved reliability.

An embodiment of the present disclosure may provide for a memory controller. The memory controller according to an embodiment of the present disclosure may control a semiconductor memory device including a plurality of pages. The memory controller may include a processing unit and a command control unit. The processing unit may receive a command and a logical address corresponding to the command from a host, and may generate a command physical address by converting the logical address. The command control unit may temporarily store a cache physical address corresponding to cache data that is cached in a page buffer of the semiconductor memory device, and may convert the command by comparing the cache physical address to the command physical address.

In an embodiment, the command control unit may include a command queue, a page buffer logging unit, and a command conversion unit. The command queue may temporarily store the command and the command physical address. The page buffer logging unit may temporarily store the cache physical address. The command conversion unit may receive the cache physical address from the page buffer logging unit, compare the cache physical address to the command physical address, and convert the command based on a result of the comparison.

In an embodiment, the command may include a data read command and a data output command. Further, when the cache physical address is identical to the command physical address, the command conversion unit may convert the command by deleting the data read command from the command.

An embodiment of the present disclosure may provide for a memory controller. The memory controller according to an embodiment of the present disclosure may control a semiconductor memory device including a plurality of pages. The memory controller may include a processing unit, a page buffer logging unit, and a command control unit. The processing unit may receive a command and a logical address corresponding to the command from a host, and may generate a command physical address by converting the logical address. The page buffer logging unit may temporarily store a cache physical address corresponding to cache data that is cached in a page buffer of the semiconductor memory device. The command control unit may convert the command by comparing the cache physical address to the command physical address.

In an embodiment, the command control unit may include a command queue and a command conversion unit. The command queue may temporarily store the command and the command physical address. The command conversion unit may receive the cache physical address from the page buffer logging unit, compare the cache physical address to the command physical address, and convert the command based on a result of the comparison.

An embodiment of the present disclosure may provide for a method of operating a memory controller. By means of the method of operating a memory controller according to an embodiment of the present disclosure, a semiconductor memory device may be controlled. The method of operating the memory controller may include receiving a command and a logical address corresponding to the command from a host, receiving a cache physical address corresponding to cache data that is cached in a page buffer of the semiconductor memory device, comparing a command physical address corresponding to the logical address to the cache physical address, and converting the command based on a result of the comparison.

### BRIEF DESCRIPTION OF THE DRAWINGS

FIG. 1 is a block diagram illustrating a storage device in accordance with an embodiment of the present disclosure.

FIG. 2 is a block diagram illustrating a semiconductor memory device of FIG. 1.

FIG. 3 is a diagram illustrating an embodiment of a memory cell array of FIG. 2.

FIG. 4 is a circuit diagram illustrating an example of any one memory block BLKa of the memory blocks BLK1 to BLKz of FIG. 3.

FIG. 5 is a circuit diagram illustrating an example of any one memory block BLKb of the memory blocks BLK1 to BLKz of FIG. 3.

FIG. 6 is a circuit diagram illustrating an example of any one memory block BLKc of the memory blocks BLK1 to BLKz included in the memory cell array 110 of FIG. 2.

FIG. 7 is a block diagram explaining an operation of a read and write circuit of FIG. 2.

FIG. 8 is a diagram explaining a program operation of the read and write circuit.

FIG. 9 is a diagram explaining a read operation of the read and write circuit.

FIG. 10 is a diagram explaining a data output operation of the read 1o and write circuit.

FIG. 11 is a block diagram illustrating a memory controller according to an embodiment of the present disclosure.

FIG. 12 is a block diagram illustrating an exemplary embodiment of a command control unit illustrated in FIG. 11.

FIG. 13 is a diagram illustrating in detail the operation of the command control unit.

FIG. 14 is a diagram explaining a command conversion operation.

FIG. 15 is a diagram illustrating an example of data stored in a page buffer logging unit.

FIG. 16 is a block diagram illustrating a semiconductor memory device including four planes.

FIG. 17 is a diagram illustrating an example of data stored in the page buffer logging unit.

FIG. 18 is a block diagram illustrating a memory controller according to an embodiment of the present disclosure.

FIG. 19 is a block diagram illustrating an exemplary embodiment of a command control unit illustrated in FIG. 18.

FIG. 20 is a flowchart explaining a method of operating a memory controller according to an embodiment of the present disclosure.

FIG. 21 is a flowchart explaining in detail the received command conversion step of FIG. 18.

FIG. 22 is a block diagram illustrating an embodiment of a storage device including a controller according to the present disclosure.

FIG. 23 is a block diagram illustrating an embodiment of a storage device including a controller according to the present disclosure.

FIG. 24 is a block diagram illustrating an application example of the storage device of FIG. 22 or 23.

FIG. 25 is a block diagram illustrating a computer system including the storage device described above with reference to FIG. 22 or 23.

### DETAILED DESCRIPTION

Various embodiments of the present invention are described below in more detail with reference to the accompanying drawings. We note, however, that the present invention may be embodied in different forms and variations, and should not be construed as being limited to the embodiments set forth herein. Rather, the described embodiments are provided so that this disclosure will be thorough and complete, and will fully convey the present invention to those skilled in the art to which this invention pertains. Throughout the disclosure, like reference numerals refer to like parts throughout the various figures and embodiments of the present invention. Moreover, reference to “an embodiment” does not necessarily mean only one embodiment, and different references to “an embodiment” are not necessarily to the same embodiment(s).

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The phrase “at least one of . . . and . . . ,” when used herein with a list of items, means a single item from the list or any combination of items in the list. For example, “at least one of A, B, and C” means, only A, or only B, or only C, or any combination of A, B, and C.

The drawings are not necessarily to scale and, in some instances, proportions may have been exaggerated in order to clearly illustrate features of the embodiments.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The terminology used herein is for the purpose of describing particular embodiments only and is not intended to be limiting of the present invention.

As used herein, singular forms may include the plural forms and vice versa, unless the context clearly indicates otherwise.

It is also noted, that in some instances, as would be apparent to those skilled in the relevant art, an element also referred to as a feature described in connection with one embodiment may be used singly or in combination with other elements of another embodiment, unless specifically indicated otherwise.

It will be further understood that the terms “comprises,” “comprising,” “may include,” and “including” when used in this specification, specify the presence of the stated elements and do not preclude the presence or addition of one or more other elements. As used herein, the term “and/or” may include any and all combinations of one or more of the associated listed items.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

Hereinafter, the various embodiments of the present invention will be described in detail with reference to the attached drawings.

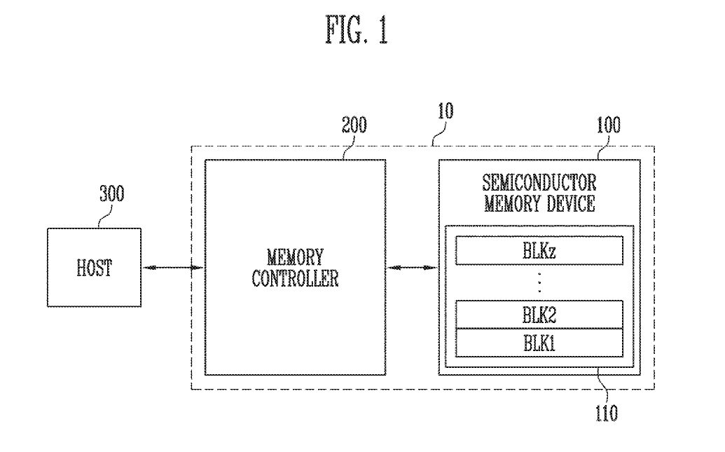

FIG. 1 is a block diagram illustrating a storage device 10 in accordance with an embodiment of the present disclosure.

Referring FIG. 1, the storage device 10 may include a semiconductor memory device 100 and a memory controller 200. Further, the storage device 10 communicates with a host 300. The semiconductor memory device 100 may include a memory cell array 110, which may include a plurality of memory blocks BLK1, BLK2, . . . , BLKz (hereinafter, referred to as ‘BLK1 to BLKz’). The memory controller 200 controls the overall operation of the semiconductor memory device 100. Further, the memory controller 200 controls the operation of the semiconductor memory device 100 in response to a command received from the host 300.

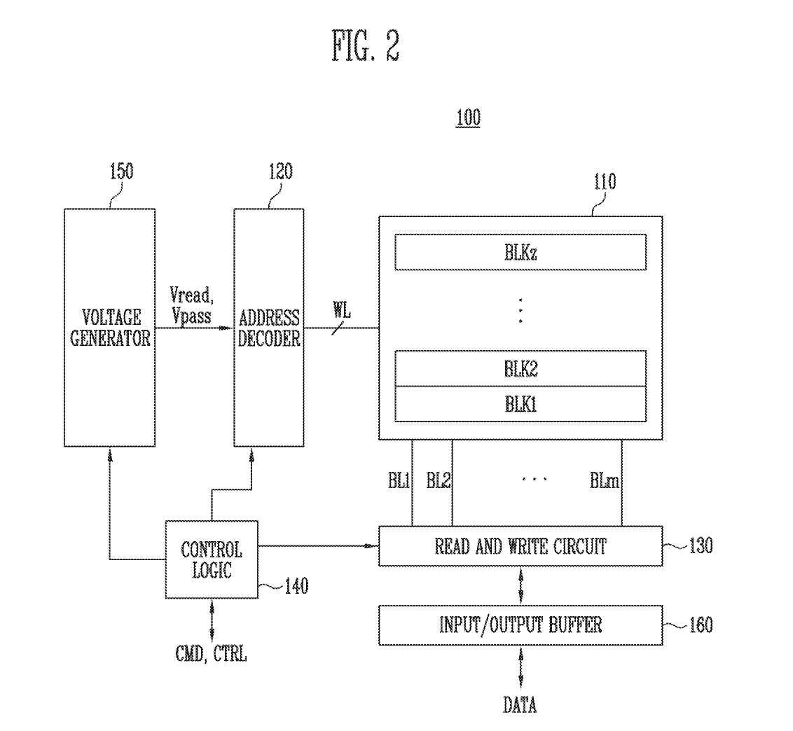

FIG. 2 is a block diagram illustrating the semiconductor memory device 100 of FIG. 1.

Referring to FIG. 2, the semiconductor memory device 100 may include a memory cell array 110, an address decoder 120, a read and write circuit 130, a control logic 140, a voltage generator 150, and an input/output buffer 160.

The memory cell array 110 may include a plurality of memory blocks BLK1 to BLKz. The memory blocks BLK1 to BLKz may be coupled to the address decoder 120 through word lines WL. The memory blocks BLK1 to BLKz may be coupled to the read and write circuit 130 through bit lines BL1 to BLm. Each of the memory blocks BLK1 to BLKz may include a plurality of memory cells. In an embodiment, the plurality of memory cells may be nonvolatile memory cells, and may be implemented as nonvolatile memory cells having a vertical channel structure. The memory cell array 110 may be implemented as a memory cell array having a two-dimensional (2D) structure. In an embodiment, the memory cell array 110 may be implemented as a memory cell array having a three-dimensional (3D) structure. Each of the memory cells included in the memory cell array may store at least one bit of data. In various embodiments, each of the memory cells included in the memory cell array 110 may be a single-level cell (SLC) that stores 1-bit data, a multi-level cell (MLC) that stores 2-bit data, a triple-level cell that stores 3-bit data, or a quad-level cell that stores 4-bit data. In various embodiments, the memory cell array 110 may include a plurality of memory cells, each of which stores 5 or more bits of data.

The address decoder 120, the read and write circuit 130, the control logic 140, and the voltage generator 150 may operate as a peripheral circuit for driving the memory cell array 110. The address decoder 120 is coupled to the memory cell array 110 through the word lines WL. The address decoder 120 may operate under the control of the control logic 140. The address decoder 120 may receive addresses through the input/output buffer 160 provided in the semiconductor memory device 100.

The address decoder 120 may decode a block address, among the received addresses. The address decoder 120 selects at least one memory block based on the decoded block address. When a read voltage application operation is performed during a read operation, the address decoder 120 may apply a read voltage Vread, generated by the voltage generator 150, to a selected word line of a selected memory block, and may apply a pass voltage Vpass to remaining unselected word lines. During a program verify operation, the address decoder 120 may apply a verify voltage, generated by the voltage generator 150, to a selected word line of a selected memory block, and may apply the pass voltage Vpass to remaining unselected word lines.

The address decoder 120 may decode a column address, among the received addresses. The address decoder 120 may transmit the decoded column address to the read and write circuit 130.

The read and program operations of the semiconductor memory device 100 are each performed on a page-by-page basis. Addresses received at the request of read and program operations may include a block address, a row address, and a column address. The address decoder 120 may select one memory block and one word line in accordance with the block address and the row address. The column address may be decoded by the address decoder 120, and may then be provided to the read and write circuit 130.

The address decoder 120 may include a block decoder, a row decoder, a column decoder, an address buffer, etc.

The read and write circuit 130 may include a plurality of page buffers PB1 to PBm (not shown). The read and write circuit 130 may operate as a “read circuit” during a read operation of the memory cell array 110 and as a “write circuit” during a write operation thereof. The plurality of page buffers PB1 to PBm are coupled to the memory cell array 110 through the bit lines BL1 to BLm. In order to sense threshold voltages of the memory cells during a read or program verify operation, the page buffers PB1 to PBm may continuously supply sensing current to the bit lines coupled to the memory cells while each of the page buffers PB1 to PBm senses, through a sensing node, a change in the amount of flowing current depending on the program state of a corresponding memory cell and latches it as sensing data. The read and write circuit 130 may operate in response to page buffer control signals outputted from the control logic 140.

During a read operation, the read and write circuit 130 may sense data stored in the memory cells and temporarily store read data, and may then output data DATA to the input/output buffer 160 of the semiconductor memory device 100. In an embodiment, the read and write circuit 130 may further include a column select circuit or the like (not shown), in addition to the page buffers (or page resistors).

The control logic 140 is coupled to the address decoder 120, the read and write circuit 130, and the voltage generator 150. The control logic 140 may receive a command CMD and a control signal CTRL through the input/output buffer 160 of the semiconductor memory device 100. The control logic 140 may control the overall operation of the semiconductor memory device 100 in response to the control signal CTRL. The control logic 140 may output a control signal for controlling a precharge potential level at the sensing node of the plurality of page buffers PB1 to PBm. The control logic 140 may control the read and write circuit 130 to perform a read operation of the memory cell array 110.

The voltage generator 150 may generate a read voltage Vread and a pass voltage Vpass required for a read operation in response to a control signal outputted from the control logic 140. The voltage generator 150 may include a plurality of pumping capacitors for receiving an internal supply voltage to generate a plurality of voltages having various voltage levels, and may generate a plurality of voltages by selectively enabling the plurality of pumping capacitors under the control of the control logic 140.

The address decoder 120, the read and write circuit 130, and the voltage generator 150 may function as peripheral circuits that perform a read operation, a write operation, and an erase operation on the memory cell array 110. The peripheral circuits may perform a read operation, a write operation, and an erase operation on the memory cell array 110 under the control of the control logic 140.

FIG. 3 is a diagram Illustrating an embodiment of the memory cell array 110 of FIG. 2.

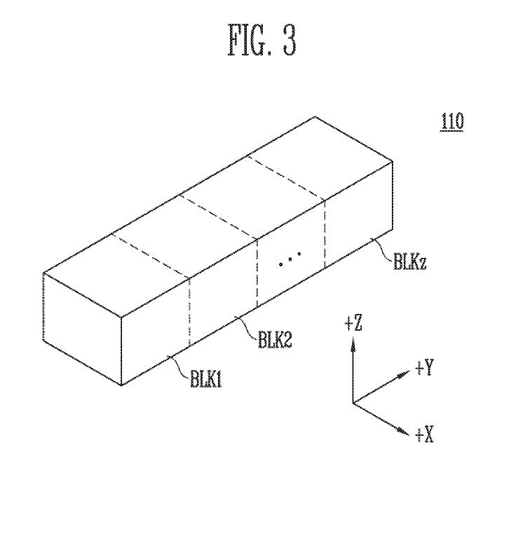

Referring to FIG. 3, the memory cell array 110 may include a plurality of memory blocks BLK1 to BLKz. Each memory block may have a three-dimensional (3D) structure. Each memory block may include a plurality of memory cells stacked on a substrate. Such memory cells are arranged along a positive X (+X) direction, a positive Y (+Y) direction, and a positive Z (+Z) direction. The structure of each memory block will be described in detail below with reference to FIGS. 4 and 5.

FIG. 4 is a circuit diagram illustrating an example of any one memory block BLKa of the memory blocks BLK1 to BLKz of FIG. 3.

Referring to FIG. 4, the memory block BLKa may include a plurality of cell strings CS11 to CS1m and CS21 to CS2m. In an embodiment, each of the cell strings CS11 to CS1m and CS21 to CS2m may be formed in a ‘U’ shape. In the memory block BLKa, m cell strings are arranged in a row direction (i.e. a positive (+) X direction). In FIG. 4, two cell strings are illustrated as being arranged in a column direction (i.e. a positive (+) Y direction). However, this is merely an illustration and the present disclosure is not limited thereto. That is, three or more cell strings may be arranged in the column direction.

Each of the plurality of cell strings CS11 to CS1m and CS21 to CS2m may include at least one source select transistor SST, first to n-th memory cells MC1 to MCn, a pipe transistor PT, and at least one drain select transistor DST.

The select transistors SST and DST and the memory cells MC1 to MCn may have similar structures, respectively. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided to each cell string. In an embodiment, a pillar for providing at least one of the channel layer, the tunneling insulating layer, the charge storage layer, and the blocking insulating layer may be provided to each cell string.

The source select transistor SST of each cell string is connected between the common source line CSL and memory cells MC1 to MCp.

In an embodiment, the source select transistors of cell strings arranged in the same row are coupled to a source select line extended in a row direction, and source select transistors of cell strings arranged in different rows are coupled to different source select lines. For example, in FIG. 4, source select transistors of cell strings CS11 to CS1m in a first row are coupled to a first source select line SSL1. The source select transistors of cell strings CS21 to CS2m in a second row are coupled to a second source select line SSL2.

In an embodiment, source select transistors of the cell strings CS11 to CS1m and CS21 to CS2m may be coupled in common to a single source select line.

The first to n-th memory cells MC1 to MCn in each cell string are coupled between the source select transistor SST and the drain select transistor DST.

The first to n-th memory cells MC1 to MCn may be divided into first to p-th memory cells MC1 to MCp and p+1-th to n-th memory cells MCp+1 to MCn. The first to p-th memory cells MC1 to MCp are sequentially arranged in a direction opposite a positive (+) Z direction and are connected in series between the source select transistor SST and the pipe transistor PT. The p+1-th to n-th memory cells MCp+1 to MCn are sequentially arranged in the +Z direction and are connected in series between the pipe transistor PT and the drain select transistor DST. The first to p-th memory cells MC1 to MCp and the p+1-th to n-th memory cells MCp+1 to MCn are coupled to each other through the pipe transistor PT. The gates of the first to n-th memory cells MC1 to MCn of each cell string are coupled to first to n-th word lines WL1 to WLn, respectively.

The gate of the pipe transistor PT of each cell string is coupled to a pipeline PL.

The drain select transistor DST of each cell string is connected between the corresponding bit line and the memory cells MCp+1 to MCn. The cell strings in a row direction are coupled to drain select lines extended in a row direction. Drain select transistors of cell strings CS11 to CS1m in the first row are coupled to a first drain select line DSL1. Drain select transistors of cell strings CS21 to CS2m in a second row are coupled to a second drain select line DSL2.

Cell strings arranged in a column direction are coupled to bit lines extended in a column direction. For example, in FIG. 4, cell strings CS11 and CS21 in a first column are coupled to a first bit line BL1. Cell strings CS1m and CS2m in an m-th column are coupled to an m-th bit line BLm.

The memory cells coupled to the same word line in cell strings arranged in a row direction constitute a single page. For example, memory cells coupled to the first word line WL1, among the cell strings CS11 to CS1m in the first row, constitute a single page. Memory cells coupled to the first word line WL1, among the cell strings CS21 to CS2m in the second row, constitute a single additional page. Cell strings arranged in the direction of a single row may be selected by selecting any one of the drain select lines DSL1 and DSL2. A single page may be selected from the selected cell strings by selecting any one of the word lines WL1 to WLn.

In an embodiment, instead of first to m-th bit lines BL1 to BLm, even bit lines and odd bit lines may be provided. In that case, even-numbered cell strings, among the cell strings CS11 to CS1m or CS21 to CS2m arranged in a row direction, may be coupled to the even bit lines, respectively, and odd-numbered cell strings, among the cell strings CS11 to CS1m or CS21 to CS2m arranged in the row direction, may be coupled to the odd bit lines, respectively.

In an embodiment, one or more of the first to n-th memory cells MC1 to MCn may be used as dummy memory cells. For example, one or more dummy memory cells are provided to reduce an electric field between the source select transistor SST and the memory cells MC1 to MCp. Alternatively, the one or more dummy memory cells are provided to reduce an electric field between the drain select transistor DST and the memory cells MCp+1 to MCn. As more dummy memory cells are provided, the reliability of the operation of the memory block BLKa is improved, but the size of the memory block BLKa is increased. As fewer memory cells are provided, the size of the memory block BLKa is reduced, but the reliability of the operation of the memory block BLKa may be deteriorated.

In order to efficiently control the one or more dummy memory cells, each of the dummy memory cells may have a required threshold voltage. Before or after the erase operation of the memory block BLKa is performed, a program operation may be performed on all or some of the dummy memory cells. When an erase operation is performed after the program operation has been performed, the threshold voltages of the dummy memory cells control the voltages that are applied to the dummy word lines coupled to respective dummy memory cells, and thus the dummy memory cells may have required threshold voltages.

FIG. 5 is a circuit diagram illustrating an example of any one memory block BLKb of the memory blocks BLK1 to BLKz of FIG. 3.

Referring to FIG. 5, the memory block BLKb may include a plurality of cell strings CS11′ to CS1m′ and CS21′ to CS2m′. Each of the plurality of cell strings CS11′ to CS1m′ and CS21′ to CS2m′ is extended along a positive Z (+Z) direction. Each of the cell strings CS11′ to CS1m′ and CS21′ to CS2m′ may include at least one source select transistor SST, first to n-th memory cells MC1 to MCn, and at least one drain select transistor DST, which are stacked on a substrate (not illustrated) below the memory block BLKb.

The source select transistor SST of each cell string is connected between a common source line CSL and memory cells MC1 to MCn. The source select transistors of cell strings arranged in the same row are coupled to the same source select line. For example, in FIG. 5, source select transistors of cell strings CS11′ to CS1m′ arranged in a first row are coupled to a first source select line SSL1. Source select transistors of cell strings CS21′ to CS2m′ arranged in a second row are coupled to a second source select line SSL2. In an embodiment, source select transistors of the cell strings CS11′ to CS1m′ and CS21′ to CS2m′ may be coupled in common to a single source select line.

The first to n-th memory cells MC1 to MCn in each cell string are connected in series between the source select transistor SST and the drain select transistor DST. The gates of the first to n-th memory cells MC1 to MCn are coupled to first to n-th word lines WL1 to WLn, respectively.

The drain select transistor DST of each cell string is connected between the corresponding bit line and the memory cells MC1 to MCn. Drain select transistors of cell strings arranged in a row direction are coupled to drain select lines extended in a row direction. The drain select transistors of the cell strings CS11′ to CS1m′ in the first row are coupled to a first drain select line DSL1. The drain select transistors of the cell strings CS21′ to CS2m′ in the second row are coupled to a second drain select line DSL2.

As a result, the memory block BLKb of FIG. 5 has a circuit similar to that of the memory block BLKa of FIG. 4 except that a pipe transistor PT is excluded from each cell string.

In an embodiment, instead of first to m-th bit lines BL1 to BLm, even bit lines and odd bit lines may be provided. In that case, even-numbered cell strings, among the cell strings CS11′ to CS1m′ or CS21′ to CS2m′ arranged in a row direction, may be coupled to the even bit lines, respectively, and odd-numbered cell strings, among the cell strings CS11′ to CS1m′ or CS21′ to CS2m′ arranged in the row direction, may be coupled to the odd bit lines, respectively.

In an embodiment, one or more of the first to n-th memory cells MC1 to MCn may be used as dummy memory cells. For example, the one or more dummy memory cells are provided to reduce an electric field between the source select transistor SST and the memory cells MC1 to MCn. Alternatively, the one or more dummy memory cells are provided to reduce an electric field between the drain select transistor DST and the memory cells MC1 to MCn. As more dummy memory cells are provided, the reliability of the operation of the memory block BLKb is improved, but the size of the memory block BLKb is increased. As fewer memory cells are provided, the size of the memory block BLKb is reduced, but the reliability of the operation of the memory block BLKb may be deteriorated.

In order to efficiently control the one or more dummy memory cells, each of the dummy memory cells may have a required threshold voltage. Before or after the erase operation of the memory block BLKb is performed, a program operation may be performed on all or some of the dummy memory cells. When an erase operation is performed after the program operation has been performed, the threshold voltages of the dummy memory cells control the voltages that are applied to the dummy word lines coupled to respective dummy memory cells, and thus the dummy memory cells may have required threshold voltages.

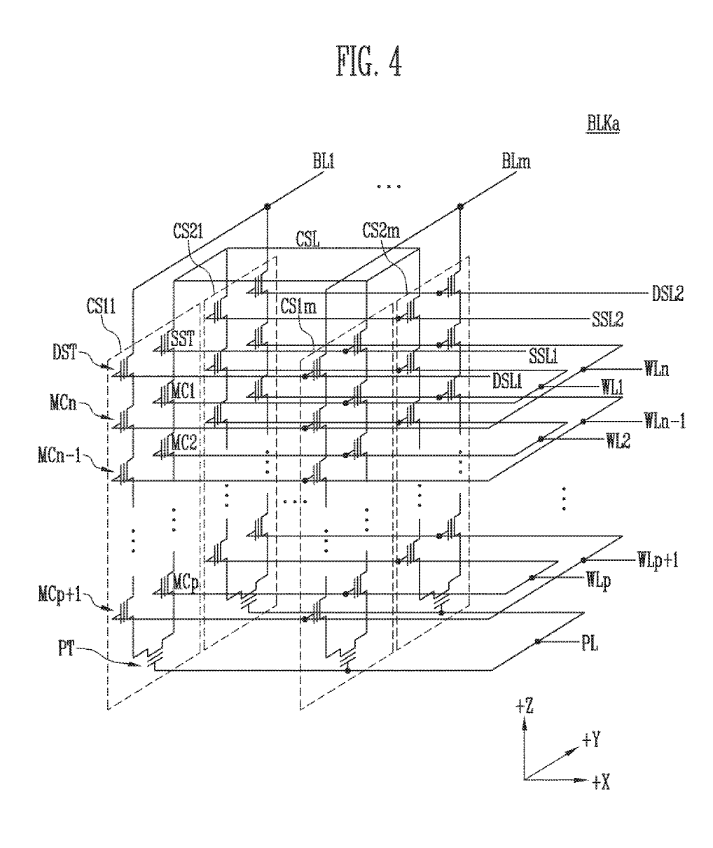

FIG. 6 is a circuit diagram illustrating an example of any one memory block BLKc of the memory blocks BLK1 to BLKz included in the memory cell array 110 of FIG. 2.

Referring to FIG. 6, the memory block BLKc may include a plurality of cell strings CS1 to CSm. The plurality of cell strings CS1 to CSm may be coupled to a plurality of bit lines BL1 to BLm, respectively. Each of the cell strings CS1 to CSm may include at least one source select transistor SST, first to n-th memory cells MC1 to MCn, and at least one drain select transistor DST.

The select transistors SST and DST and the memory cells MC1 to MCn may have similar structures. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string is coupled between a common source line CSL and the memory cells MC1 to MCn.

The first to n-th memory cells MC1 to MCn in each cell string are coupled between the source select transistor SST and the drain select transistor DST.

The drain select transistor DST of each cell string is coupled between the corresponding bit line and the memory cells MC1 to MCn.

The memory cells coupled to the same word line may constitute a single page. The cell strings CS1 to CSm may be selected by selecting the drain select line DSL. One page may be selected from the selected cell strings by selecting any one of the word lines WL1 to WLn.

In other embodiments, even bit lines and odd bit lines may be provided instead of the first to m-th bit lines BL1 to BLm. In that case, for example, among the cell strings CS1 to CSm, even-numbered cell strings may be coupled to the even bit lines, respectively, and odd-numbered cell strings may be coupled to the odd bit lines, respectively.

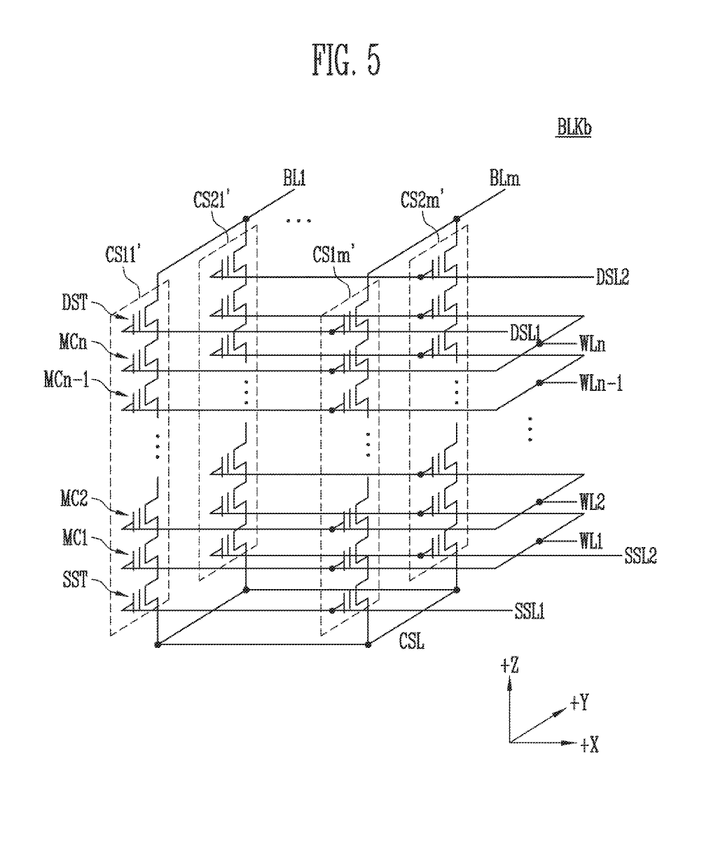

FIG. 7 is a block diagram for explaining the operation of the read and write circuit 130 of FIG. 2.

Referring to FIG. 7, the memory cell array 110 may include a plurality of memory cells, and may be accessed by word lines WL and bit lines BL. Memory cells coupled to the same word line may constitute a page 111.

The memory controller 200 may receive a command from a host and then transfer a command CMD and an address ADDR for controlling a semiconductor memory device 100. For example, when a read command together with a logical address corresponding to the page 111 is received from the host, the memory controller 200 may transfer the read command CMD and the physical address ADDR corresponding thereto to the semiconductor memory device 100. The physical address ADDR is generated by converting the logical address, received from the host, using the memory controller 200.

The control logic 140 controls peripheral circuits (not illustrated) so that pieces of data stored in respective memory cells of the page 111 are transferred to the page buffer of the read and write circuit 130 in response to the received command CMD and address. The pieces of data DATA transferred to the page buffer of the read and write circuit 130 are delivered to the memory controller 200. The memory controller 200 transfers the data DATA received from the semiconductor memory device 100 to the host.

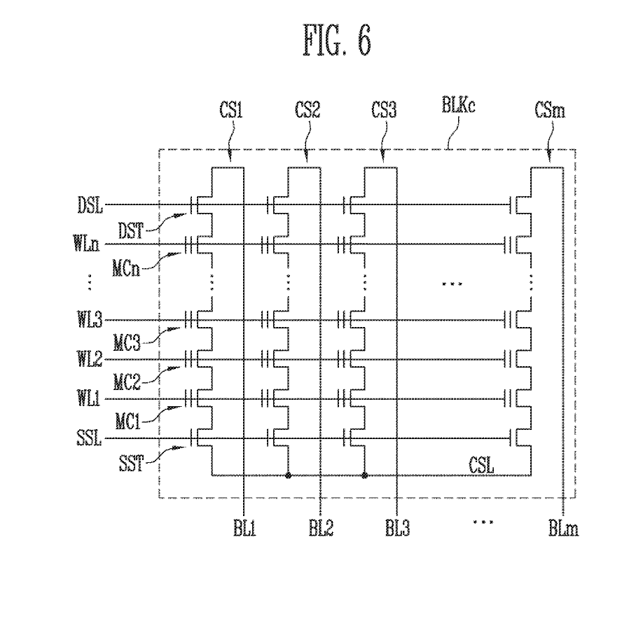

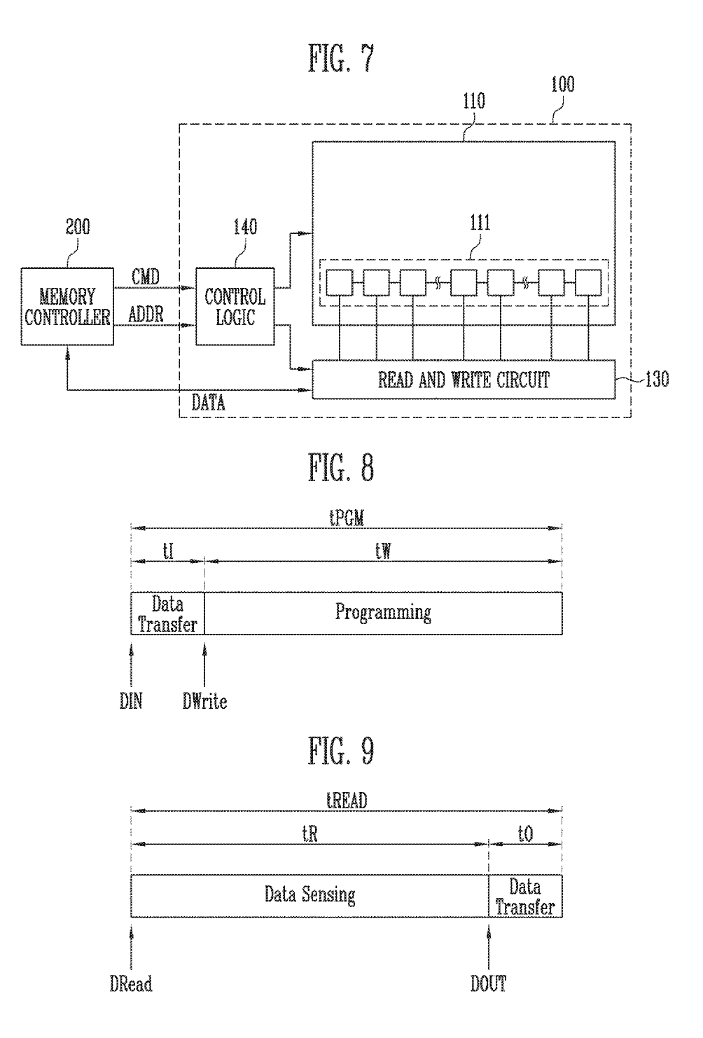

FIG. 8 is a diagram explaining a program operation of the read and write circuit 130. In describing FIG. 8, references will be made to FIG. 7.

Referring to FIG. 8, when a program operation is performed, the memory controller 200 may transmit a data input command DIN, a physical address ADDR, and data DATA to the semiconductor memory device 100. The data input command DIN, which is one of commands for requesting a program operation of the semiconductor memory device 100, may be a command for requesting that data DATA to be buffered in the page buffer of the read and write circuit 130.

The page buffer included in the read and write circuit 130 may receive data corresponding to one page, and buffer the received data during a time period tI.

When the data corresponding to one page is received, the memory controller 200 may transmit a data write command DWrite to the semiconductor memory device 100. The data write command DWrite may be a command for requesting that data DATA to be temporarily stored in the page buffer of the read and write circuit 130 be programmed to the page 111 corresponding to the physical address ADDR of the memory cell array 110.

In response to the data write command DWrite, pieces of data temporarily stored in the page buffer of the read and write circuit 130 may be programmed to the memory cell array 110. Until the programming is completed, the page buffer of the read and write circuit 130 may retain the data DATA during a time period tW.

The time period tI and the time period tW form an entire program time tPGM.

FIG. 9 is a diagram explaining a read operation of the read and write circuit 130. In describing FIG. 9, references will be made to FIG. 7.

Referring to FIG. 9, when a read operation is performed, the memory controller 200 may transmit a data read command DRead and a physical address ADDR to the semiconductor memory device 100. The data read command DRead, which is one of commands for requesting a read operation of the semiconductor memory device 100, may be a command for requesting that data DATA be stored in the memory cell array 110 be sensed and be loaded into the page buffer of the read and write circuit 130.

During a time period tR, the memory cell array 110 may be sensed, and the data stored in the memory cell array 110 may be loaded into the page buffer of the read and write circuit 130. The page buffer of the read and write circuit 130 may buffer the loaded data.

When sensing of data corresponding to one page is completed, the memory controller 200 may transmit a data output command DOUT to the semiconductor memory device 100. In response to the data output command DOUT, the page buffer of the read and write circuit 130 may transmit data DATA to the memory controller 200. The page buffer of the read and write circuit 130 may transmit the temporarily stored data to the memory controller 200 during a time period tO.

The time periods tR and tO form an entire read time tREAD.

Here, the relative ratio of individual time periods tI, tW, tR, and tO is not limited by FIGS. 8 and 9.

Even after the data DATA has been transferred to the memory controller 200, the page buffer of the read and write circuit 130 may retain the loaded data.

When the memory controller 200 receives a request to read data corresponding to the same physical address ADDR from the host in a state in which the data of the page 111 is loaded into the page buffer of the read and write circuit 130, the page buffer of the read and write circuit 130 does not need to again sense data stored in the memory cells of the page 111. Instead, the data already loaded into the page buffer of the read and write circuit 130 is immediately transferred to the memory controller 200.

In this case, the memory controller 200 may transfer only the data output command DOUT to the semiconductor memory device 100 without transmitting the data read command DRead, thus enabling the data DATA loaded into the page buffer of the read and write circuit 130 to be transmitted to the memory controller 200.

FIG. 10 is a diagram explaining a data output operation of the read and write circuit 130.

As described above, when the memory controller 200 receives a request to read data corresponding to the same physical address ADDR provided along with the previous data input command DIN from the host in a state in which data of a page 111 is loaded into the page buffer of the read and write circuit 130, the memory controller 200 may transfer only a data output command DOUT to the semiconductor memory device 100 without transmitting a data read command DRead.

Accordingly, a time period tR is not required for data sensing, and thus a time period tO forms an entire read time tREAD.

In order to perform the above operation, the memory controller 200 needs Information about the page 111 in which the data DATA is stored. The currently loaded data DATA on the page buffer of the read and write circuit 130 is the data DATA provided along with the previous data input command DIN in response to the previous request of program operation from the host. That is, the physical address ADDR of the page 111 corresponding to the data DATA stored in the page buffer of the read and write circuit 130 should be known. Further, the controller 200 may convert a logical address corresponding to the command received from the host into a physical address, and may compare the physical address to the physical address ADDR corresponding to the data DATA loaded into the page buffer of the read and write circuit 130.

When the two physical addresses are identical to each other as a result of the comparison, the memory controller 200 may transfer only the data output command DOUT to the semiconductor memory device 100, as illustrated in FIG. 10. When the two physical addresses are different from each other as a result of the comparison, the memory controller 200 may sequentially transfer the data read command DRead and the data output command DOUT to the semiconductor memory device 100, as illustrated in FIG. 9.

FIG. 11 is a block diagram illustrating the memory controller 200 of FIG. 1 according to an embodiment of the present disclosure.

Referring to FIG. 11, the memory controller 200 according to an embodiment of the present disclosure may include a processing unit 210, a command control unit 220, a host interface (I/F) 230, a random access memory (RAM) 240, and a memory interface (I/F) 250.

Respective operations of the processing unit 210, the host interface 230, the RAM 240, and the memory interface 250 will be described in detail below with reference to FIG. 22.

The processing unit 210 controls the overall operation of the memory controller 200. Meanwhile, the processing unit transfers a command received from a host to the command control unit 220. Further, the processing unit converts a logical address corresponding to the command into a physical address and transfers the physical address to the command control unit 220.

The command control unit 220 may temporarily store a physical address corresponding to data DATA currently loaded into the read and write circuit 130 of the semiconductor memory device 100.

The data DATA currently loaded into the read and write circuit 130 is called “cache data”, and the physical address ADD corresponding to the cache data is called a “cache physical address”. Meanwhile, the physical address, currently received by the command control unit 220 from the processing unit 210, that is, the physical address corresponding to the current command received from the host, is also called a “command physical address”. The current command may be a read command.

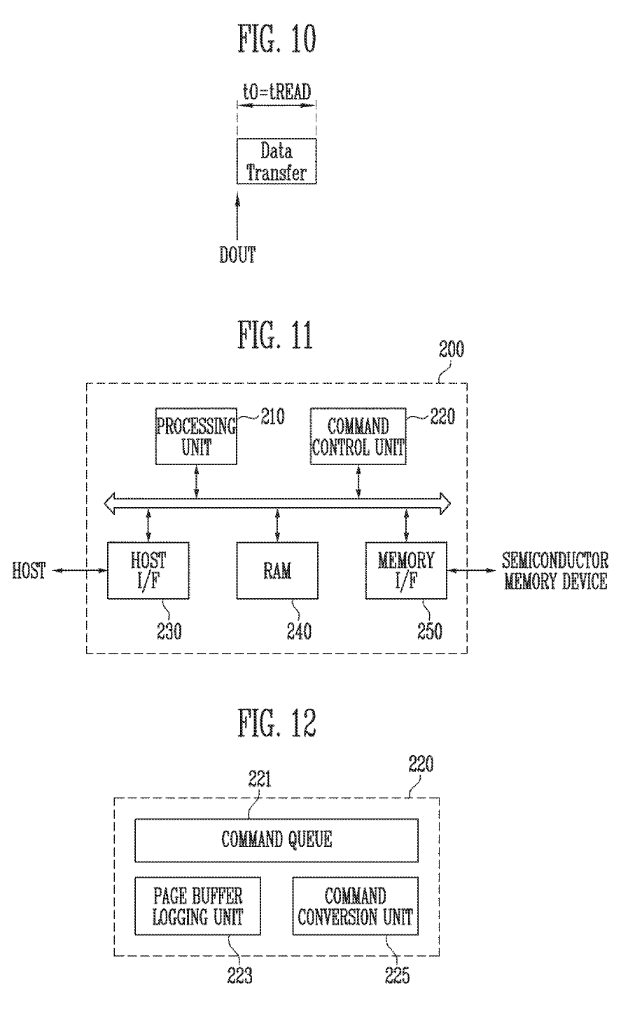

The command control unit 220 may convert the command when the command physical address is identical to the cache physical address. Conversely, the command control unit 220 does not convert the command when the command physical address is different from the cache physical address. A detailed operation of the command control unit 220 related to the conversion of the command will be described below with reference to FIGS. 12 to 14.

FIG. 12 is a block diagram illustrating an exemplary embodiment of the command control unit 220 of FIG. 11.

Referring to FIG. 12, the command control unit 220 may Include a command queue 221, a page buffer logging unit 223, and a command conversion unit 225.

The command queue 221 may queue a command and a command physical address corresponding thereto, which are received from the processing unit 210. Therefore, the command and the command physical address received by the command control unit 220 may be sequentially stored in the command queue 221.

The page buffer logging unit 223 may temporarily store a page buffer logging data including cache physical address. In an embodiment, a physical address of the page 111 corresponding to a cache data currently loaded on the page buffer of the read and write circuit 130 as illustrated in FIG. 7 may be stored as a cache physical address in the page buffer logging unit 223.

The command conversion unit 225 receives the cache physical address from the page buffer logging unit 223. Further, the command conversion unit 225 compares the cache physical address to the command physical address. The command conversion unit 225 may convert a command stored in the command queue 221 based on the result of the comparison.

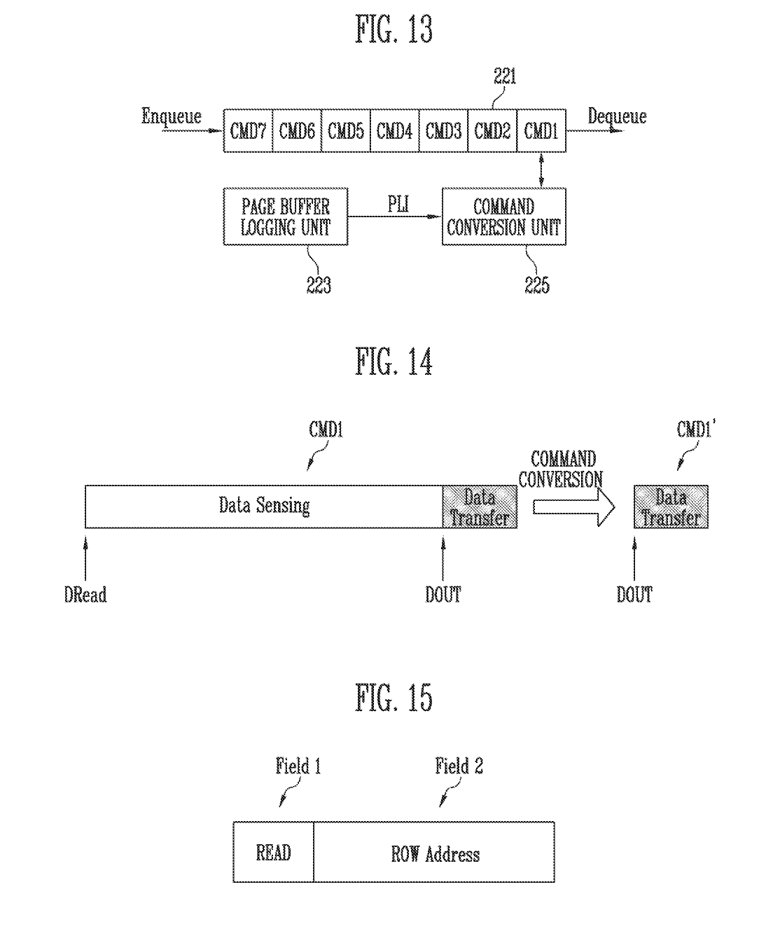

Detailed operations of respective elements of the command control unit 220 will be described below with reference to FIG. 13.

FIG. 13 is a diagram illustrating in detail the operation of the command control unit 220.

Referring to FIG. 13, received commands CMD1, CMD2, . . . , CMD7 are sequentially enqueued to the command queue 221 according to the first-in-first-out (FIFO) scheme. In detail, a command is enqueued to a rear portion of the command queue 221, and a command is dequeued from a front portion of the command queue 221. In FIG. 13, the command CMD1, which is enqueued first, is currently stored in the front portion of the command queue 221, and the command CMD7, which is enqueued last, is stored in the rear portion of the command queue 221. The command CMD1 queued in the front portion of the command queue 221 is transferred to the semiconductor memory device 100. Meanwhile, although not illustrated in FIG. 13, it can be seen that command physical addresses corresponding to the commands CMD1, . . . , CMD7 are queued together with the corresponding commands in the command queue 221.

The command conversion unit 225 receives a cache physical address PLI from the page buffer logging unit 223. The cache physical address PLI may be the physical address of the page 111 corresponding to a cache data currently loaded on the page buffer of the read and write circuit 130 as illustrated in FIG. 7.

The command conversion unit 225 may compare the cache physical address PLI received from the page buffer logging unit 223 to a command physical address corresponding to the command CMD1 stored in the command queue 221. That is, the command conversion unit 225 compares the command physical address queued in the front portion of the command queue 221 to the cache physical address PLI.

When the command physical address is identical to the cache physical address PLI, the command conversion unit 225 converts the command CMD1. Conversely, when the command physical address is different from the cache physical address PLI, the command conversion unit 225 does not convert the command CMD1. The conversion of a command will be described in detail below with reference to FIG. 14.

FIG. 14 is a diagram explaining a command conversion operation of the command conversion unit 225.

Referring to FIG. 14, a command conversion operation, performed by the command conversion unit 225 when a command physical address is identical to a cache physical address PLI, is illustrated.

When the command physical address is identical to the cache physical address PLI, data requested by the host to be read may be data DATA or the cache data which is currently loaded into the page buffer of the read and write circuit 130. Therefore, in order to reduce a read time tREAD, a data read command DRead does not need to be transmitted.

Accordingly, the command conversion unit 225 may delete the data read command DRead from the command CMD1 stored in the front portion of the command queue 221, and may then generate a converted command CMD1′. The generated converted command CMD1′ may include only a data output command DOUT. The converted command CMD1′ may be transferred to the semiconductor memory device 100, and data DATA or the cache data loaded into the page buffer of the read and write circuit 130 is immediately delivered to the memory controller 200.

When the command physical address is different from the cache physical address PLI, data requested by the host to be read may be different from the data DATA or the cache data which is currently loaded into the page buffer of the read and write circuit 130. Therefore, the command CMD1 is not converted, and the command CMD1 including both the data read command DRead and the data output command DOUT is transferred to the semiconductor memory device 100. The page buffer of the read and write circuit 130 may sense page data corresponding to a new address in response to the data read command DRead. Also, the page buffer may transfer the sensed page data to the memory controller 200 in response to the data output command DOUT.

As described above with reference to FIGS. 11 to 14, the memory controller 200 according to an embodiment of the present disclosure may include the command control unit 220 separate and independent from the processing unit 210. The processing unit 210 may merely convert a logical address corresponding to the command into a physical address, and may transfer the physical address to the command control unit 220. The command control unit 220 may queue the received command physical address in the command queue, and may convert the command by comparing a command physical address queued in the front portion of the command queue to a cache physical address. Accordingly, loading exerted on firmware of the processing unit 210 may be reduced. Therefore, the operation reliability of the memory controller may be Improved. Meanwhile, the command control unit 220 may be implemented as a physical hardware provided separately from the processing unit 210.

FIG. 15 is a diagram illustrating an example of page buffer logging data stored in the page buffer logging unit 223. Referring to FIG. 15, page buffer logging data stored in the page buffer logging unit 223 may Include two fields. In a first field Field1, information indicating the type of operation which was just previously performed on a page buffer may be stored. For example, in FIG. 15, information indication a read operation READ may be stored. In a second field Field2, a cache physical address may be stored. In FIG. 15, a row address is illustrated as being stored in the second field. In an embodiment, a block address may also be stored in the second field. It is to be noted that the page buffer logging data stored in the page buffer logging unit 223 is not limited by the example shown in FIG. 15. That is, various other types of data may be stored in the page buffer logging unit 223.

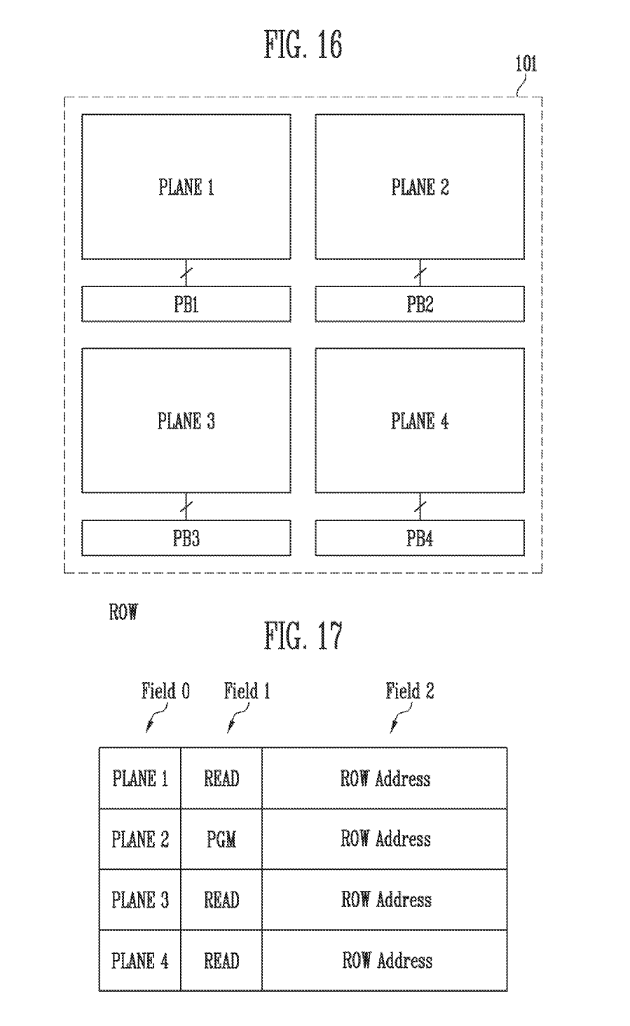

FIG. 16 is a block diagram illustrating a semiconductor memory device 101 including four planes. Referring to FIG. 16, the semiconductor memory device 101 may include first to fourth planes PLANE1 to PLANE4. Meanwhile, corresponding page buffers PB1 to PB4 may be coupled to respective planes. As illustrated in FIG. 16, when the semiconductor memory device 101 includes the four pages PB1 to PB4, the page buffer logging unit 223 may store pieces of page buffer logging data about respective page buffers.

FIG. 17 is a diagram illustrating an example of page buffer logging data stored in the page buffer logging unit 223. As illustrated in FIG. 16, when the semiconductor memory device 101 includes four page buffers PB1 to PB4, the page buffer logging unit 223 may store four page buffer logging data including cache physical addresses corresponding to page buffers PB1 to PB4, respectively. Referring to FIG. 17, each piece of page buffer logging data may Include three fields. In a 0-th field Field0, plane information may be stored, and in a first field Field1, information indicating the type of operation, which was just previously performed on the corresponding page buffer, may be stored. Meanwhile, in a second field Field2, a row address may be stored. The plane information in the 0-th field and the row address in the second field may constitute a single cache physical address.

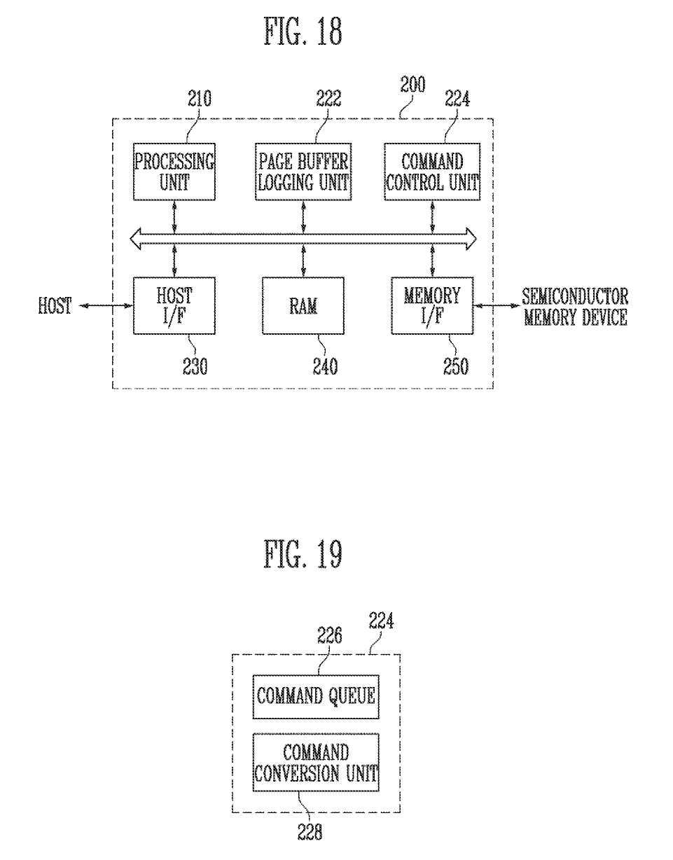

FIG. 18 is a block diagram illustrating the memory controller 200 of FIG. 1 according to another embodiment of the present disclosure.

Referring to FIG. 18, the memory controller 200 according to an embodiment of the present disclosure may include a processing unit 210, a page buffer logging unit 222, a command control unit 224, a host interface (I/F) 230, a RAM 240, and a memory interface (I/F) 250.

Respective operations of the processing unit 210, the host interface 230, the RAM 240, and the memory interface 250, illustrated in FIG. 18, will be described in detail below with reference to FIG. 23.

The processing unit 210 controls the overall operation of the memory controller 200. Meanwhile, the processing unit 210 transfers a command received from a host to the command control unit 224. Further, the processing unit 210 may convert a logical address corresponding to the command into a physical address, and may transfer the physical address to the command control unit 224.

The page buffer logging unit 222 may temporarily store a physical address corresponding to data currently loaded into the page buffer of the semiconductor memory device 100. That is, the page buffer logging unit 222 may temporarily store a “cache physical address” corresponding to “cache data” loaded into the page buffer. In an embodiment, a physical address of the page 111 corresponding to a cache data currently loaded on the page buffer of the read and write circuit 130 as illustrated in FIG. 7 may be stored as a cache physical address in the page buffer logging unit 222.

The command control unit 224 may convert the command when the command physical address is identical to the cache physical address. The command control unit 224 does not convert the command when the command physical address is different from the cache physical address.

It can be seen in FIG. 18 that the page buffer logging unit 222 is provided as a component separate from the command control unit 224. Meanwhile, referring to FIGS. 11 and 12, the page buffer logging unit 223 was provided as a component included in the command control unit 220. The page buffer logging unit 222 of FIG. 18 and the page buffer logging unit 223 of FIG. 12 may be configured to perform substantially the same operation.

FIG. 19 is a block diagram illustrating an exemplary embodiment of the command control unit 224 of FIG. 18. Referring to FIG. 19, the command control unit 224 may include a command queue 226 and a command conversion unit 228.

The command queue 226 may queue a command and a command physical address corresponding thereto, which are received from the processing unit 210. Therefore, the command and the command physical address received by the command control unit 224 may be sequentially stored in the command queue 226.

The command conversion unit 228 may receive a cache physical address from the page buffer logging unit 222 illustrated in FIG. 18. Further, the command conversion unit 228 may compare the cache physical address to the command physical address. The command conversion unit 228 may convert the command stored in the command queue 226 based on the result of the comparison.

That is, the command queue 226 and the command conversion unit 228 illustrated in FIG. 19, may perform substantially the same operation as the command queue 221 and the command conversion unit 225 illustrated in FIG. 12.

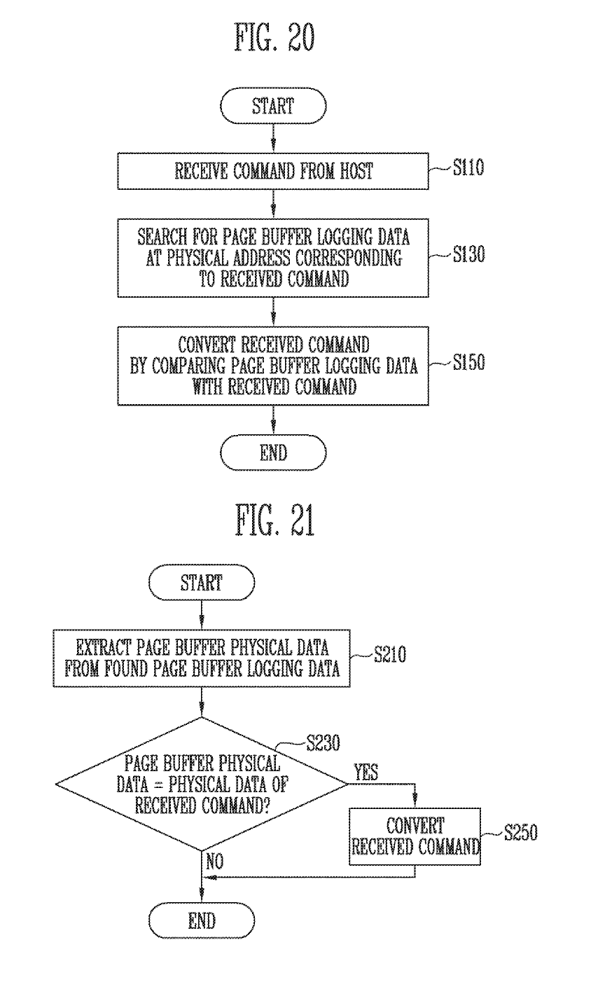

FIG. 20 is a flowchart illustrating a method of operating the memory controller 200 according to an embodiment of the present disclosure.

Referring to FIG. 20, the method of operating the memory controller 200 according to an embodiment of the present disclosure may include the step S110 of receiving a command from a host, the step S130 of searching for page buffer logging data corresponding to the received command, and the step S150 of converting the received command by comparing the page buffer logging data to the received command.

At step S110, the memory controller 200 may receive a read command from the host. Meanwhile, the memory controller 200 may receive a corresponding logical address and convert the logical address into a command physical address.

At step S130, the page buffer logging data may have a cache physical address and may be stored in the page buffer logging unit 223 or 222, as illustrated in FIG. 12 or 18. At step S130, the page buffer logging data stored in the page buffer logging unit 223 or 222 is searched.

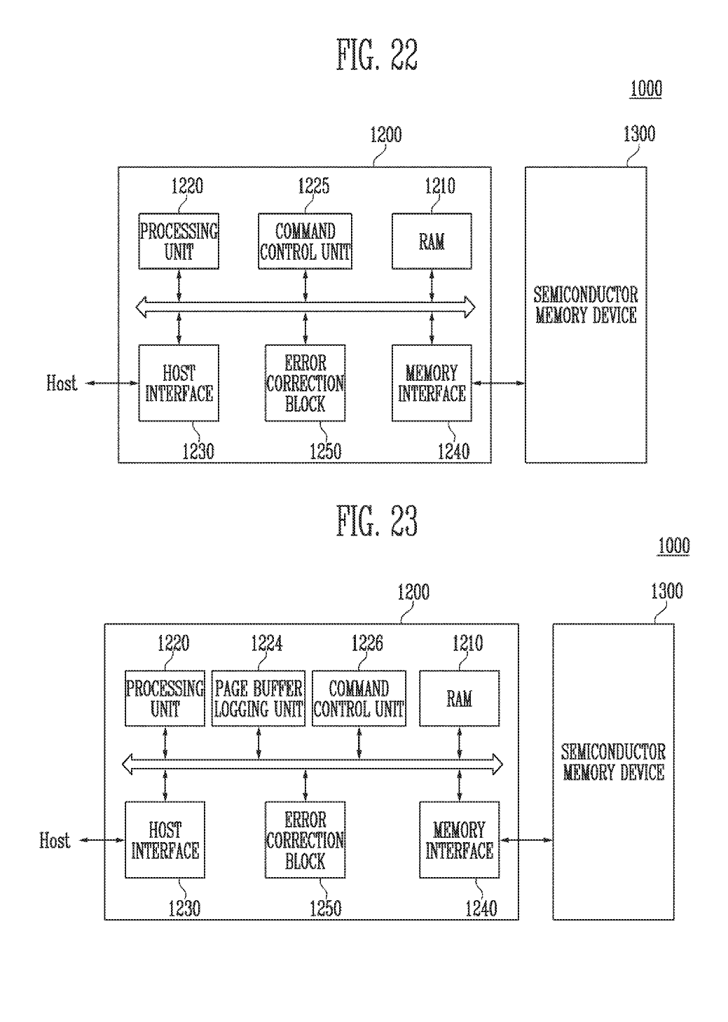

At step S150, the cache physical address included in the searched page buffer logging data is compared to the physical address of the currently received command, and then the currently received command is converted based on the result of the comparison. Step S150 will be described in detail below with reference to FIG. 21.

FIG. 21 is a flowchart illustrating in detail step S150 of converting the currently received command shown in FIG. 20.

Referring to FIG. 21, step S150 of converting the received command may include the step S210 of extracting cache physical address from page buffer logging data found as a result of the search of step S130, the step S230 of determining whether the cache physical address is Identical to the physical address of the received command, and the step S250 of converting the received command.

At step S210, a cache physical address is extracted from page buffer logging data found as a result of the search of step S130.

At step S230, the command physical address is compared to the cache physical address to determine whether the two addresses are identical to each other.

If the two addresses are identical to each other, the received command is converted at step S250 by deleting the data read command from the command, whereas if the two addresses are different from each other, step S150 is terminated without converting the received command.

It can be seen that the method illustrated in FIGS. 20 and 21 is substantially identical to the method of operating the memory controller 200, described above with reference to FIGS. 7 to 19.

FIG. 22 is a block diagram illustrating an embodiment of a storage device 1000 including a memory controller 1200 according to the present disclosure.

Referring FIG. 22, the storage device 1000 may include a semiconductor memory device 1300 and the memory controller 1200.

The semiconductor memory device 1300 may have the same configuration and operation as the semiconductor memory device 100, described above with reference to FIG. 2. The controller 1200 may have the same configuration and operation as the memory controller 200, described above with reference to FIG. 11. Hereinafter, repetitive explanations will be omitted.

The controller 1200 is coupled to a host Host and the semiconductor memory device 1300. The controller 1200 is configured to access the semiconductor memory device 1300 in response to a request from the host Host. For example, the controller 1200 is configured to control read, write, erase, and background operations of the semiconductor memory device 1300. The controller 1200 is configured to provide an interface between the host Host and the semiconductor memory device 1300. The controller 1200 is configured to run firmware for controlling the semiconductor memory device 1300.

The controller 1200 may include a RAM 1210, a processing unit 1220, a command control unit 1225, a host interface 1230, a memory interface 1240, and an error correction block 1250.

The RAM 1210 is used as any one of a work memory of the processing unit 1220, a cache memory between the semiconductor memory device 1300 and the host Host, and a buffer memory between the semiconductor memory device 1300 and the host Host.

The processing unit 1220 controls the overall operation of the controller 1200. The processing unit 1220 is configured to control a read operation, a program operation, an erase operation and a background operation of the semiconductor memory device 1300. The memory control unit 1220 is configured to run firmware for controlling the semiconductor memory device 1300. The processing unit 1220 may perform a function of a Flash Translation Layer (FTL). The processing unit 1220 may convert a logical block address (LBA), provided by the host, into a physical block address (PBA) through the FTL. The FTL may receive the LBA using a mapping table and may convert the LBA into the PBA. Address mapping methods performed through the FTL include various methods according to a mapping unit. Representative address mapping methods include a page mapping method, a block mapping method, and a hybrid mapping method.

The command control unit 1225 may have the same configuration as the command control unit 220, illustrated in FIG. 12. The command control unit 1225 may search for page buffer logging data at a physical address corresponding to a received command, and may then convert the received command by comparing found page buffer logging data with the received command.

The host interface 1230 may include a protocol for performing data exchange between the host Host and the controller 1200. In an exemplary embodiment, the controller 1200 is configured to communicate with the host Host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, and an integrated drive electronics (IDE) protocol, and a private protocol.

The memory interface 1240 interfaces with the semiconductor memory device 1300. For example, the memory interface 1240 may include a NAND interface or NOR interface.

The error correction block 1250 is configured to use an error correcting code (ECC) to detect and correct an error in data received from the semiconductor memory device 1300. The error correction block 1250 may correct errors from read page data using an ECC. The error correction block 1250 may correct errors using a low density parity check (LDPC) code, a Bose, Chaudhri, Hocquenghem (BCH) Code, a turbo code, a Reed-Solomon code, a convolution code, a recursive systematic code (RSC), or coded modulation such as trellis-coded modulation (TCM), block coded modulation (BCM), or hamming code.

The controller 1200 and the semiconductor memory device 1300 may be integrated into a single semiconductor device. In an exemplary embodiment, the controller 1200 and the semiconductor memory device 1300 may be integrated into a single semiconductor device to form a memory card. For example, the controller 1200 and the semiconductor memory device 1300 may be integrated into a single semiconductor device and form a memory card such as a personal computer memory card international association (PCMCIA), a compact flash card (CF), a smart media card (SM or SMC), a memory stick, a multimedia card (MMC, RS-MMC, or MMCmicro), a SD card (SD, miniSD, microSD, or SDHC), or a universal flash storage (UFS).

The controller 1200 and the semiconductor memory device 1300 may be integrated into a single semiconductor device to form a solid state drive (SSD). The solid state drive (SSD) may include the storage device 1000 configured to store data in the semiconductor memory device 1300. When the storage device 1000 is used as the SSD, an operation speed of the host Host coupled to the storage device 1000 may be phenomenally improved.

In an embodiment, the storage device 1000 may be provided as one of various elements of an electronic device such as a computer, a ultra mobile PC (UMPC), a workstation, a net-book, a personal digital assistants (PDA), a portable computer, a web tablet, a wireless phone, a mobile phone, a smart phone, an e-book, a portable multimedia player (PMP), a game console, a navigation device, a black box, a digital camera, a 3-dimensional television, a digital audio recorder, a digital audio player, a digital picture recorder, a digital picture player, a digital video recorder, a digital video player, a device capable of transmitting/receiving information in an wireless environment, one of various devices for forming a home network, one of various electronic devices for forming a computer network, one of various electronic devices for forming a telematics network, an RFID device, one of various elements for forming a computing system, or the like.

In an exemplary embodiment, the semiconductor memory device 1300 or the storage device 1000 may be embedded in various types of packages. For example, the semiconductor memory device 1300 or the storage device 1000 may be packaged in a type such as Package on Package (PoP), Ball grid arrays (BGAs), Chip scale packages (CSPs), Plastic Leaded Chip Carrier (PLCC), Plastic Dual In Line Package (PDIP), Die in Waffle Pack, Die in Wafer Form, Chip On Board (COB), Ceramic Dual In Line Package (CERDIP), Plastic Metric Quad Flat Pack (MQFP), Thin Quad Flatpack (TQFP), Small Outline Integrated Circuit (SOIC), Shrink Small Outline Package (SSOP), Thin Small Outline Package (TSOP), Thin Quad Flatpack (TQFP), System In Package (SIP), Multi-Chip Package (MCP), Wafer-level Fabricated Package (WFP), Wafer-Level Processed Stack Package (WSP), or the like.

FIG. 23 is a block diagram illustrating an embodiment of a storage device 1000 including a memory controller 1200 according to the present disclosure.

Referring FIG. 23, the storage device 1000 may include a semiconductor memory device 1300 and the memory controller 1200.

The semiconductor memory device 1300 may have the same configuration and operation as the semiconductor memory device 100, described above with reference to FIG. 2. The controller 1200 may have the same configuration and operation as the memory controller 200, described above with reference to FIG. 18. Hereinafter, repetitive explanations will be omitted.

The controller 1200 may include a RAM 1210, a processing unit 1220, a page buffer logging unit 1224, a command control unit 1226, a host interface 1230, a memory interface 1240, and an error correction block 1250.

The page buffer logging unit 1224 may be provided as a component separate from the command control unit 1226, and may temporarily store a “cache physical address” corresponding to “cache data” loaded into a page buffer.

The command control unit 1226 may have the same configuration as the command control unit 224, illustrated in FIG. 19. The command control unit 1226 may search for page buffer logging data at a physical address corresponding to a received command, and may convert the received command by comparing found page buffer logging data with the received command.

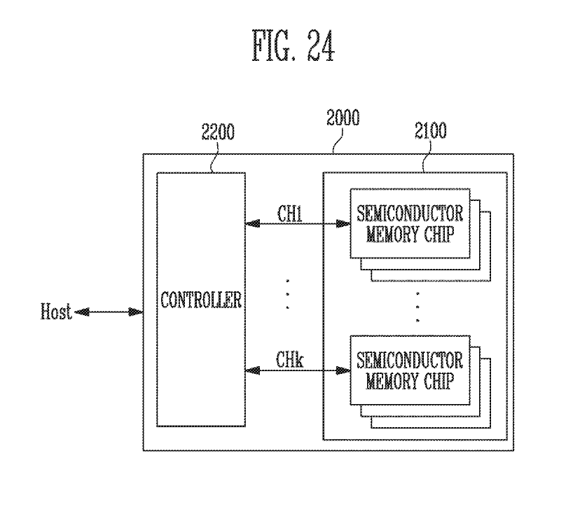

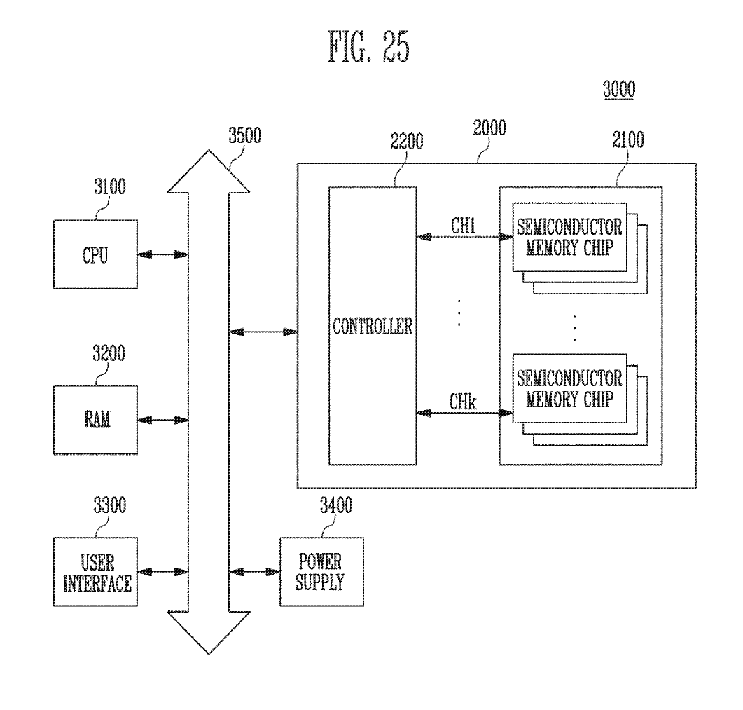

FIG. 24 is a block diagram Illustrating an application example of the storage device 2000 of FIG. 22 or 23.

Referring to FIG. 24, the storage device 2000 may include a semiconductor memory device 2100 and a controller 2200. The semiconductor memory device 2100 may include a plurality of semiconductor memory chips. The semiconductor memory chips are divided into a plurality of groups.

In FIG. 24, it is illustrated that each of the plurality of groups communicates with the controller 2200 through first to k-th channels CH1 to CHk. Each semiconductor memory chip may have the same configuration and operation as the semiconductor memory device 100, described above with reference to FIG. 2.

Each group communicates with the controller 2200 through one common channel. The controller 2200 has the same configuration as the controller 1200, described above with reference to FIG. 22, and is configured to control the plurality of memory chips of the semiconductor memory device 2100 through the plurality of channels CH1 to CHk.

In FIG. 24, a description has been made such that a plurality of semiconductor memory chips are coupled to a single channel. However, it will be understood that the storage device 2000 may be modified such that a single semiconductor memory chip is coupled to a single channel.

FIG. 25 is a block diagram illustrating a computing system 300 including the storage device 2000 described with reference to FIG. 22 or 23.

Referring to FIG. 25, the computing system 3000 may Include a central processing unit (CPU) 3100, a RAM 3200, a user interface 3300, a power supply 3400, a system bus 3500, and a storage device 2000.

The storage device 2000 is electrically coupled to the CPU 3100, the RAM 3200, the user interface 3300, and the power supply 3400 through the system bus 3500. Data provided through the user interface 3300 or processed by the CPU 3100 is stored in the storage device 2000.

In FIG. 25, the semiconductor memory device 2100 is illustrated as being coupled to the system bus 3500 through the controller 2200. However, the semiconductor memory device 2100 may be directly coupled to the system bus 3500. The function of the controller 2200 may be performed by the CPU 3100 and the RAM 3200.

In FIG. 25, the storage device 2000 described with reference to FIG. 24 is illustrated as being provided. However, the storage device 2000 may be replaced with the storage device 1000 described with reference to FIG. 22 or 23. In an embodiment, the computing system 3000 may be configured to include all of the storage devices 1000 and 2000 described with reference to FIGS. 22, 23, and 24.

In accordance with an embodiment of the present disclosure, there may be provided a memory controller, which has improved reliability.

In accordance with an embodiment of the present disclosure, there may be provided a method of operating a memory controller, which has improved reliability.

While the exemplary embodiments of the present disclosure have been disclosed for illustrative purposes, those skilled in the art will appreciate that various modifications, additions and substitutions are possible. Therefore, the scope of the present disclosure must be defined by the appended claims and equivalents of the claims rather than by the description preceding them.

Although the embodiments of the present disclosure have been disclosed, those skilled in the art will appreciate that various modifications, additions and substitutions are possible, without departing from the scope and spirit of the present disclosure.

Therefore, the scope of the present disclosure must be defined by the appended claims and equivalents of the claims rather than by the description preceding them.

In the above-discussed embodiments, all steps may be selectively performed or skipped. In addition, the steps in each embodiment may not always be sequentially performed in regular order, and may be performed in another order. Furthermore, the embodiments disclosed in the present specification and the drawings aims to help those with ordinary knowledge in this art more clearly understand the present disclosure rather than aiming to limit the bounds of the present disclosure. In other words, one of ordinary skill in the art to which the present disclosure belongs will be able to easily understand that various modifications are possible based on the technical scope of the present disclosure.

Embodiments of the present disclosure have been described with reference to the accompanying drawings, and specific terms or words used in the description should be construed in accordance with the spirit of the present disclosure without limiting the subject matter thereof. It should be understood that many variations and modifications of the basic inventive concept described herein will still fall within the spirit and scope of the present disclosure as defined in the appended claims and their equivalents.

What is claimed is:

1. A memory controller for controlling a semiconductor memory device including a plurality of pages, comprising:
a processing unit configured to receive a command and a logical address corresponding to the command from a host, and to generate a command physical address by converting the logical address; and
a command control unit configured to temporarily store a cache physical address corresponding to cache data that is cached in a page buffer of the semiconductor memory device and to convert the command by comparing the cache physical address to the command physical address.

2. The memory controller according to claim 1, wherein the command is a read command.

3. The memory controller according to claim 2, wherein the command control unit comprises:
a command queue configured to temporarily store the command and the command physical address;
a page buffer logging unit configured to temporarily store the cache physical address; and
a command conversion unit configured to receive the cache physical address from the page buffer logging unit, compare the cache physical address to the command physical address, and convert the command based on a result of the comparison.

4. The memory controller according to claim 3, wherein:
the command comprises a data read command and a data output command, and
when the cache physical address is identical to the command physical address, the command conversion unit is configured to convert the command by deleting the data read command from the command.

5. The memory controller according to claim 4, wherein the command conversion unit is configured to compare a command physical address located in a front portion of the command queue to the cache physical address.

6. The memory controller according to claim 3, wherein the page buffer logging unit is configured to update the cache physical address when a read operation of the semiconductor memory device is completed.

7. The memory controller according to claim 3, wherein the command physical address is a row address of data loaded into the page buffer.

8. The memory controller according to claim 6, wherein the page buffer logging unit comprises:
a first field configured to store information indicating a type of operation most recently performed on the page buffer; and
a second field configured to store a row address or a block address;

9. A memory controller for controlling a semiconductor memory device including a plurality of pages, comprising:
a processing unit configured to receive a command and a logical address corresponding to the command from a host, and generate a command physical address by converting the logical address;
a page buffer logging unit configured to temporarily store a cache physical address corresponding to cache data that is cached in a page buffer of the semiconductor memory device; and
a command control unit configured to convert the command by comparing the cache physical address with the command physical address.

10. The memory controller according to claim 9, wherein the command is a read command.

11. The memory controller according to claim 10, wherein the command control unit comprises:
a command queue configured to temporarily store the command and the command physical address; and
a command conversion unit configured to receive the cache physical address from the page buffer logging unit, compare the cache physical address to the command physical address, and convert the command based on a result of the comparison.

12. The memory controller according to claim 11, wherein:
the command comprises a data read command and a data output command, and
when the cache physical address is identical to the command physical address, the command conversion unit is configured to convert the command by deleting the data read command from the command.

13. The memory controller according to claim 12, wherein the command conversion unit is configured to compare a command physical address located in a front portion of the command queue to the cache physical address.

14. The memory controller according to claim 11, wherein the page buffer logging unit is configured to update the cache physical address when a read operation of the semiconductor memory device is completed.

15. The memory controller according to claim 11, wherein the command physical address is a row address of data loaded into the page buffer.

16. A method of operating a memory controller for controlling a semiconductor memory device, the method comprising:
receiving a command and a logical address corresponding to the command from a host;
receiving a cache physical address corresponding to cache data that is cached in a page buffer of the semiconductor memory device;
comparing a command physical address corresponding to the logical address with the cache physical address; and
converting the command based on a result of the comparison.

17. The method according to claim 16, wherein the command is a read command.

18. The method according to claim 17, wherein:
the command comprises a data read command and a data output command, and
converting the command is configured to convert the command, when the cache physical address is identical to the command physical address, by deleting the data read command from the command.

19. The method according to claim 16, further comprising updating the cache physical address when an operation of the semiconductor memory device corresponding to the command is completed.
